(19) United States
(12) Patent Application Publication
(10) Pub. No.: US 2025/0372389 A1
(43) Pub. Date: Dec. 4, 2025

(54) METHOD OF MANUFACTURING A SEMICONDUCTOR DEVICE

(71) Applicant: Samsung Electronics Co., Ltd., Suwon-si (KR)

(72) Inventor: Kang In KIM, Suwon-si (KR)

(73) Assignee: Samsung Electronics Co., Ltd., Suwon-si (KR)

(21) Appl. No.: 19/055,060

(22) Filed: Feb. 17, 2025

(30) Foreign Application Priority Data
Jun. 4, 2024 (KR) 10-2024-0073256

(51) Int. Cl. H01L 21/308; H01L 21/311

(52) U.S. Cl. CPC H01L 21/3086; H01L 21/31144

(57) ABSTRACT

A method of manufacturing a semiconductor device includes forming a lower insulating layer on a substrate, forming line patterns extending in a first direction, forming a mask structure on the line patterns, forming a photoresist pattern including a first opening on the mask structure, etching the mask structure using the photoresist pattern, etching the line patterns using the etched mask, etching the lower insulating layer using the etched line patterns to form lower patterns, and etching the substrate using the lower patterns. The line patterns include a first line pattern overlapping the first opening, and a second line pattern and a third line pattern adjacent to the first line pattern. The first opening includes a first inner wall, a second inner wall facing the first inner wall, and a third inner wall between the first and second inner walls.

### CROSS-REFERENCE TO RELATED APPLICATIONS

This U.S. non-provisional patent application claims priority under 35 U.S.C. § 119 to Korean Patent Application No.10-2024-0073256 filed on Jun. 4, 2024, in the Korean Intellectual Property Office, the entire contents of which are hereby incorporated by reference.

### BACKGROUND OF THE INVENTION

The inventive concepts relate to a method of manufacturing a semiconductor device, and more particularly, relate to a method of manufacturing a semiconductor device including a mask pattern.

Due to their small-sizes, multitude of functions, and/or low-cost characteristics, semiconductor devices are being esteemed as important elements in the electronic industry. Semiconductor devices may be classified into a memory device for storing data, a logic device for processing data, and a hybrid device including both of memory and logic elements.

Recently, a desire for high speeds and low power consumption of electronic products may require that semiconductor devices embedded in the electronic products should have high operating speeds and/or low operating voltages. However, an increase in the integration of semiconductor devices may cause a reduction in electrical properties and production yields of semiconductor devices. Therefore, many studies have been conducted to improve electrical properties and production yields of semiconductor devices.

### SUMMARY

Some example embodiments of the inventive concepts are to provide a semiconductor device with improved electrical characteristics and reliability and a method of manufacturing the same.

A method of manufacturing a semiconductor device according to some example embodiments of the inventive concepts may include providing a substrate, forming a lower insulating layer on the substrate, forming line patterns extending in a first direction on the lower insulating layer, the line patterns being spaced apart from each other in a second direction, the second direction being perpendicular to the first direction, forming a mask structure on the line patterns, forming a photoresist pattern including a first opening on the mask structure, etching the mask structure using the photoresist pattern as a first etch mask, etching the line patterns using the etched mask structure as a second etch mask, etching the lower insulating layer using the etched line patterns as a third etch mask to form lower patterns, and etching the substrate using the lower patterns as a fourth etch mask. The line patterns include a first line pattern overlapping the first opening, and a second line pattern and a third line pattern adjacent to the first line pattern. The first opening includes a first inner wall, a second inner wall facing the first inner wall, and a third inner wall between the first and second inner walls. The third inner wall overlaps the first line pattern, and a distance in the second direction between the first and second inner walls of the first opening is equal to or smaller than a distance in the second direction between the second and third line patterns.

A method of manufacturing a semiconductor device according to some example embodiments of the inventive concepts may include providing a substrate, forming a lower insulating layer on the substrate, forming line patterns extending in a first direction on the lower insulating layer, the line patterns being spaced apart from each other in a second direction, the second direction being perpendicular to the first direction, forming a mask structure on the line patterns, forming a photoresist pattern including an opening on the mask structure, etching the mask structure using the photoresist pattern as a first etch mask, etching the line patterns using the etched mask structure as a second etch mask, etching the lower insulating layer using the etched line patterns as a third etch mask to form lower patterns, and etching the substrate using the lower patterns as a fourth etch mask. The opening includes a first inner wall and a second inner wall parallel to the first direction, and a third inner wall and a fourth inner wall parallel to the second direction.

A method of manufacturing a semiconductor device according to some example embodiments of the inventive concepts may include providing a substrate, forming a lower insulating layer on the substrate, forming line patterns extending in a first direction on the lower insulating layer, the line patterns being spaced apart from each other in a second direction, the second direction being perpendicular to the first direction, forming a mask structure on the line patterns, forming a photoresist pattern including an opening on the mask structure, etching the mask structure using the photoresist pattern as a first etch mask, etching the line patterns using the etched mask structure as a second etch mask, etching the lower insulating layer using the etched line patterns as a third etch mask to form lower patterns, and etching the substrate using the lower patterns as a fourth etch mask. The line patterns include a first line pattern overlapping the opening, and a second line pattern and a third line pattern adjacent to the first line pattern. The opening includes a first inner wall, a second inner wall facing the first inner wall, a third inner wall between the first and second inner walls, a first connection surface connecting the first and third inner walls. A second connection surface connecting the second and third inner walls, the first connection surface is between the first and second line patterns, and the second connection surface is between the first and third line patterns.

### BRIEF DESCRIPTION OF THE DRAWINGS

Some example embodiments will be more clearly understood from the following brief description taken in conjunction with the accompanying drawings. The accompanying drawings represent non-limiting, example embodiments as described herein.

FIG. 1A is a plan view of a semiconductor device according to some example embodiments.

FIG. 1B is an enlarged view of region ‘E’ in FIG. 1A.

FIG. 1C is a cross-sectional view taken along line A-A′ in FIG. 1B.

FIG. 1D is a cross-sectional view taken along line B-B′ in FIG. 1B.

FIG. 1E is a cross-sectional view taken along line C-C′ in FIG. 1B.

FIG. 2A, 3A, 6A, 7A, and 8A are enlarged views of region ‘E’ in FIG. 1A for explaining a method of manufacturing a semiconductor device according to some example embodiments.

FIG. 3E is an enlarged view of region ‘F’ in FIG. 3A.

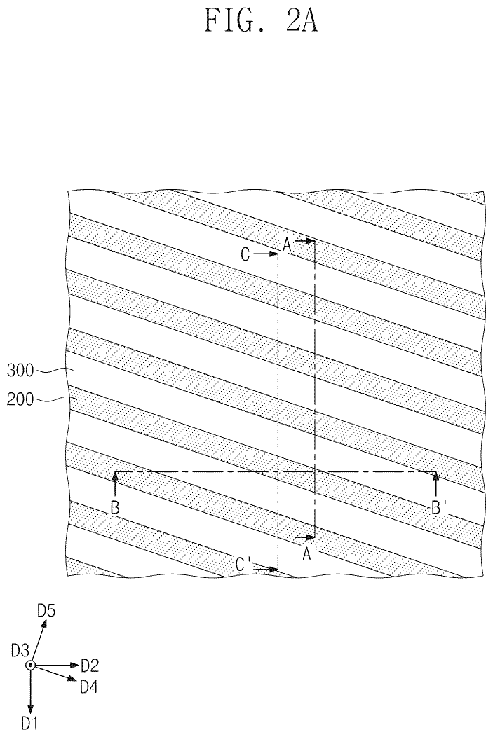

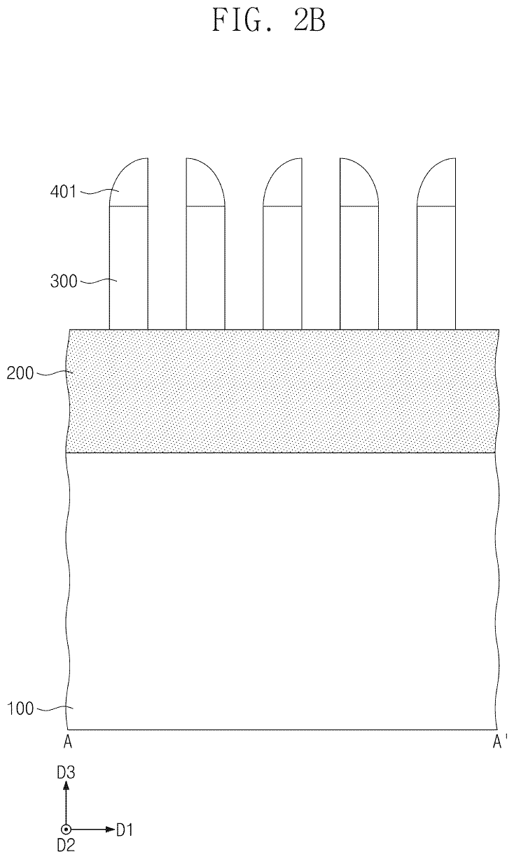

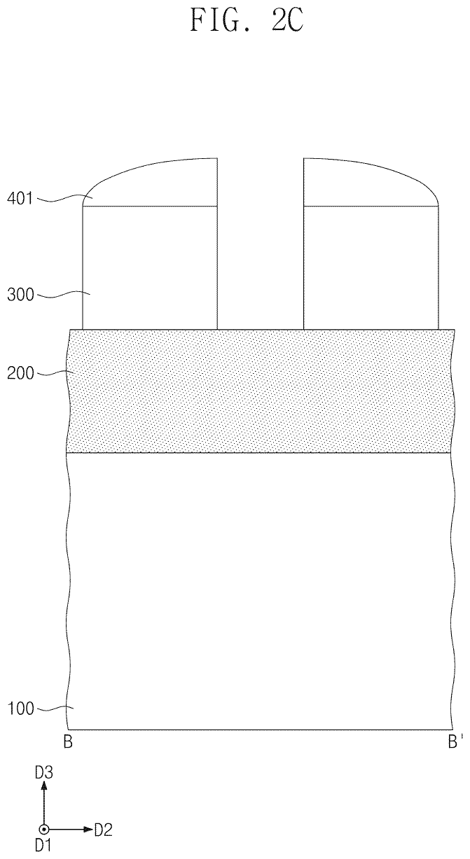

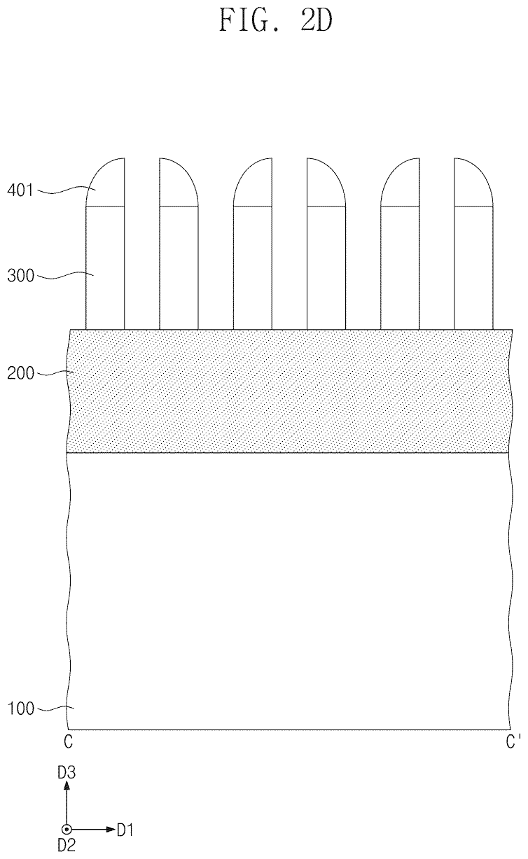

FIGS. 2B, 2C, 2D, 3B, 3C, 3D, 4A, 4B, 4C, 5A, 5B, 5C, 6B, 6C, 6D, 7B, 7C, 7D, 8B, 8C, and 8D are cross-sectional views for explaining a method of manufacturing a semiconductor device according to some example embodiments.

### DETAILED DESCRIPTION

Hereinafter, a semiconductor device and a manufacturing method thereof according to some example embodiments of the inventive concepts will be described in detail with reference to the drawings.

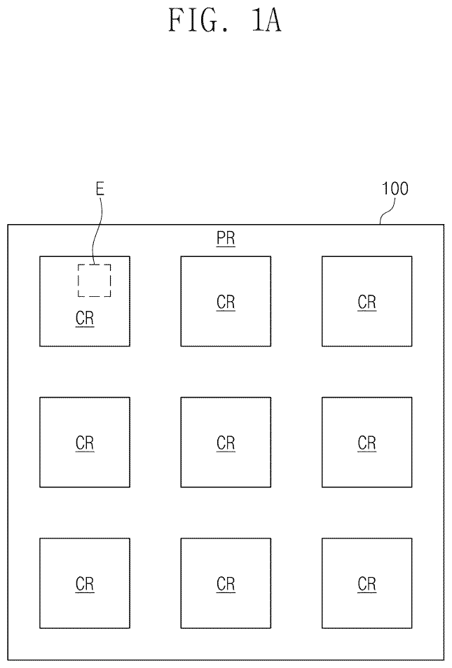

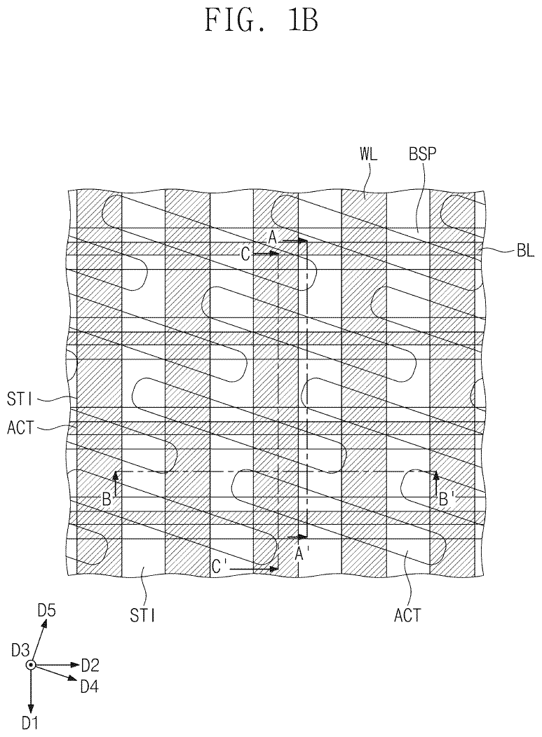

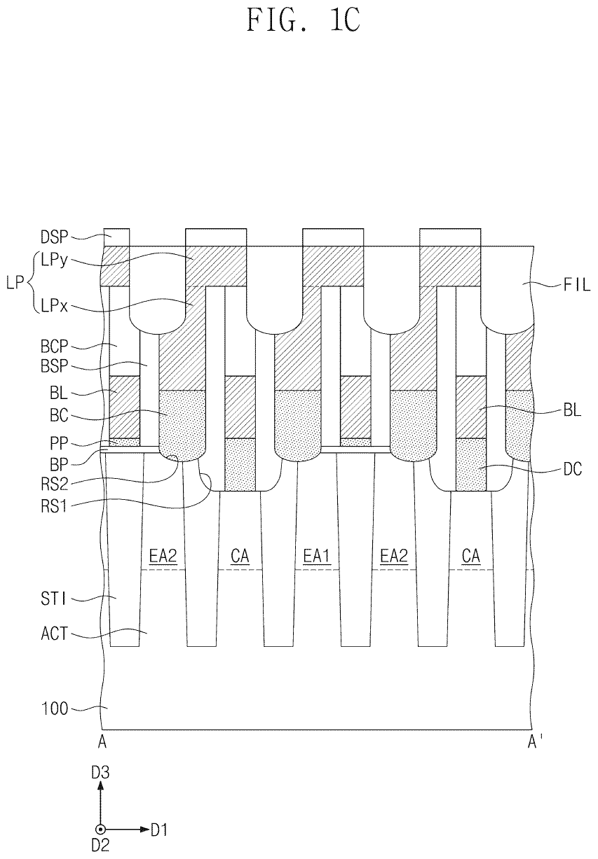

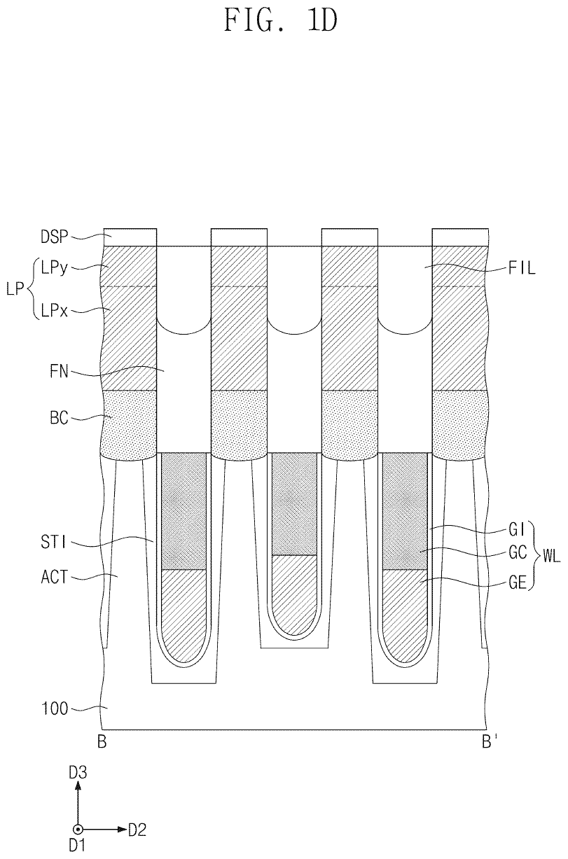

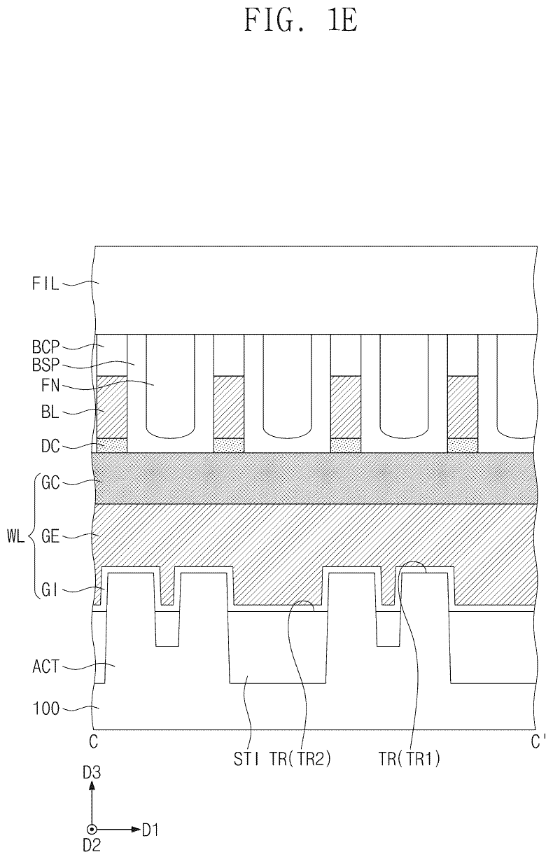

FIG. 1A is a plan view of a semiconductor device according to some example embodiments. FIG. 1B is an enlarged view of region ‘E’ in FIG. 1A. FIG. 1C is a cross-sectional view taken along line A-A′ in FIG. 1B. FIG. 1D is a cross-sectional view taken along line B-B′ in FIG. 1B. FIG. 1E is a cross-sectional view taken along line C-C′ in FIG. 1B.

Referring to FIGS. 1A to 1E, a semiconductor device may include a substrate 100. In some example embodiments, the substrate 100 may be a semiconductor substrate. As an example, the substrate 100 may include silicon, germanium, silicon-germanium, GaP, or GaAs. In some example embodiments, the substrate 100 may be a silicon-on-insulator (SOI) substrate or a germanium-on-insulator (GOI) substrate. However, example embodiments are not limited thereto. The substrate 100 may have a shape of a plate extending along a plane extending in a first direction D1 and a second direction D2. The first direction D1 and the second direction D2 may intersect each other. For example, the first direction D1 and the second direction D2 may be horizontal directions orthogonal to each other.

The substrate 100 may include cell regions CR and a peripheral region PR surrounding the cell regions CR. Each of the cell regions CR may include a cell circuit such as a memory integrated circuit. The peripheral region PR may include various peripheral circuits necessary for operation of the cell circuit, and the peripheral circuits may be electrically connected to the cell circuit.

The substrate 100 may include active patterns ACT. Upper portions of the substrate 100 protruding in a third direction D3 may be defined as active patterns ACT. The third direction D3 may intersect the first direction D1 and the second direction D2. For example, the third direction D3 may be a vertical direction orthogonal to the first direction D1 and the second direction D2.

Each of the active patterns ACT may have an island shape separated from each other. Each of the active patterns ACT may extend in a fourth direction D4. The fourth direction D4 may intersect the first direction D1, the second direction D2, and the third direction D3. For example, the fourth direction D4 may be a horizontal direction orthogonal to the third direction D3.

Each of the active patterns ACT may have a bar shape elongated in the fourth direction D4 parallel to a lower surface of the substrate 100. The active patterns ACT may be spaced apart from each other in the fourth direction D4 and a fifth direction D5. The fifth direction D5 may intersect the first direction D1, the second direction D2, the third direction D3, and the fourth direction D4. For example, the fifth direction D5 may be a horizontal direction orthogonal to the third direction D3 and the fourth direction D4.

A device isolation layer STI defining active patterns ACT may be provided. Each active pattern ACT may be surrounded by the device isolation layer STI. The device isolation layer STI may include an insulating material.

The active pattern ACT may include a first edge portion EA1 and a second edge portion EA2 spaced apart from each other in the first direction D1, and a center portion CA therebetween. The first edge portion EA1 and the second edge portion EA2 may be both ends of the active pattern ACT in the fourth direction D4. The center portion CA may be portion of the active pattern ACT interposed between the first and second edge portions EA1 and EA2, and in more detail, may be a portion of the active pattern ACT interposed between a pair of word lines WL, which will be described later. Impurities (e.g., n-type or p-type impurities) may be doped into the first and second edge portions EA1 and EA2 and the center portion CA.

The word line WL may cross the active patterns ACT and the device isolation layer STI. A plurality of word lines WL may be provided. The word lines WL may be spaced apart from each other in the second direction D2. For example, a pair of word lines WL adjacent to each other in the second direction D2 may cross one active pattern ACT. Each of the word lines WL may be disposed in each of the active patterns ACT and each of trench regions TR provided in the device isolation layer STI.

Each of the word lines WL may include a gate electrode GE, a gate dielectric pattern GI, and a gate capping pattern GC. The gate electrode GE may penetrate the active patterns ACT and the device isolation layer STI in the first direction D1. The gate dielectric pattern GI may be interposed between the gate electrode GE and the active patterns ACT, and between the gate electrode GE and the device isolation layer STI. The gate capping pattern GC may cover an upper surface of the gate electrode GE. As an example, the gate electrode GE may include a conductive material. For example, the gate electrode GE may be a single layer formed of a single material or a composite layer containing two or more materials. As an example, the gate dielectric pattern GI may include at least one of silicon oxide (SiO₂) and a high dielectric material. In this specification, a high dielectric material is defined as a material that has a higher dielectric constant than silicon oxide. As an example, the gate capping pattern GC may include silicon nitride (SiN). However, example embodiments are not limited thereto.

A buffer pattern BP may be provided on the substrate 100. The buffer pattern BP may cover the active patterns ACT and the device isolation layer STI. As an example, the buffer pattern BP may be a single layer or a composite layer. As an example, the buffer pattern BP may include at least one of silicon oxide (SiO₂), silicon nitride (SiN), and silicon oxynitride (SiON). However, example embodiments are not limited thereto.

First recess regions RS1 may be provided on an upper portion of each of the active patterns ACT and on an upper portion of the device isolation layer STI adjacent to the upper portion each of the active patterns ACT.

A bit line contact DC may be provided on the first recess region RS1. The bit line contact DC may be interposed between the center portion CA of the active pattern ACT and a bit line BL, which will be described later. A plurality of bit line contacts DC may be provided. The bit line contacts DC may be spaced apart from each other in the first and second directions D1 and D2. The bit line contacts DC may electrically connect the corresponding bit line BL and the center portion CA of the corresponding active pattern ACT. As an example, the bit line contact DC may include at least one of polysilicon and metal materials doped or undoped with impurities (e.g., Ti, Mo, W, Cu, Al, Ta, Ru, Ir, etc.). However, example embodiments are not limited thereto.

A bit line BL may be provided on the bit line contact DC. The bit line BL may extend in the second direction D2 on the bit line contact DC. A plurality of bit lines BL may be provided. The bit lines BL may be spaced apart from each other in the first direction D1. As an example, the bit line BL may include a metal material (e.g., Ti, Mo, W, Cu, Al, Ta, Ru, Ir, etc.). However, example embodiments are not limited thereto.

An insulating pattern PP may be provided between the bit line BL and the buffer pattern BP, and between bit line contacts DC adjacent to each other in the second direction D2. A plurality of insulating patterns PP may be provided. As an example, the insulating patterns PP may be spaced apart from each other in the first direction D1 and the second direction D2. An upper surface of the insulating pattern PP may be positioned at substantially the same height as an upper surface of the bit line contact DC and may be substantially coplanar. As an example, the insulating pattern PP may include polysilicon doped with impurities.

A bit line capping pattern BCP may be provided on the bit line BL. The bit line capping pattern BCP may extend in the second direction D2 along the bit line BL. A plurality of bit line capping patterns BCP may be provided. The bit line capping patterns BCP may be spaced apart from each other in the first direction D1. The bit line capping pattern BCP may vertically overlap the bit line BL. The bit line capping pattern BCP may include a single layer or multiple layers.

Bit line spacers BSP may be provided on a side surface of the bit line contact DC, a side surface of the bit line BL and a side surface of the bit line capping pattern BCP. The bit line spacer BSP may extend in the second direction D2 on the side surface of the bit line BL. The bit line spacer BSP may fill the first recess region RS1 and extend on the side surface of the bit line capping pattern BCP in the third direction D3. A plurality of bit line spacers BSP may be provided. The bit line spacers BSP may be spaced apart from each other in the first direction D1. As an example, the bit line spacer BSP may include at least one of silicon oxide (SiO₂), silicon nitride (SiN), silicon oxycarbide (SiOC), and silicon oxycarbonitride (SiOCN). However, example embodiments are not limited thereto. The bit line spacer BSP may include a single layer or multiple layers.

The storage node contact BC may be provided between neighboring bit lines BL in the first direction D1. A plurality of storage node contacts BC may be provided. The storage node contacts BC may be spaced apart from each other in the first and second directions D1 and D2. The storage node contacts BC adjacent to each other in the first direction D1 may be spaced apart from each other with the bit line BL interposed therebetween. The storage node contacts BC adjacent to each other in the second direction D2 may be spaced apart from each other with a fence pattern FN, which will be described later, interposed therebetween. Each of the storage node contacts BC may fill a second recess region RS2 provided on the corresponding edge portion of the first and second edge portions EA1 and EA2 of the active patterns ACT and may be connected to the corresponding edge portion. As an example, the storage node contact BC may include at least one of polysilicon and metal materials doped or undoped with impurities (e.g., Ti, Mo, W, Cu, Al, Ta, Ru, Ir, etc.). However, example embodiments are not limited thereto.

The fence pattern FN may be interposed between neighboring bit lines BL in the first direction D1 on the word line WL. The fence pattern FN may be interposed between neighboring storage node contacts BC in the second direction D2 on the word line WL. A plurality of fence patterns FN may be provided. The fence patterns FN may be spaced apart from each other in the first and second directions D1 and D2. The fence patterns FN adjacent to each other in the first direction D1 may be spaced apart from each other with the bit line BL therebetween. The fence patterns FN that are adjacent to each other in the second direction D2 may be spaced apart from each other with the storage node contact BC therebetween. As an example, the fence pattern FN may include at least one of silicon oxide (SiO₂), silicon nitride (SiN), silicon oxycarbide (SiOC), and silicon oxycarbonitride (SiOCN). However, example embodiments are not limited thereto.

Landing pads LP may be provided. The landing pad LP may be provided on the storage node contact BC. The landing pad LP may include a conductive material. As an example, the landing pad LP may include metal. In some example embodiments, a metal silicide layer not shown may be provided between the storage node contact BC and the landing pad LP. In some example embodiments, a barrier layer may be provided between the storage node contact BC and the landing pad LP.

The landing pad LP may include an upper portion LPy and a lower portion LPx. The upper portion LPy of the landing pad LP may be a portion disposed at a higher level than the bit line capping pattern BCP. The lower portion LPx of the landing pad LP may be connected to the storage node contact BC. The upper portion LPy of the landing pad LP may be provided on the lower portion LPx of the landing pad LP. A portion of the upper portion LPy of the landing pad LP may overlap a portion of the storage node contact BC in the third direction D3. In some example embodiments, the entire landing pad LP may be placed at a higher level than the bit line capping pattern BCP.

A filling pattern FIL may be provided on the fence pattern FN. The filling pattern FIL may be spaced apart from the landing pads LP. The filling pattern FIL may surround the landing pad LP. The filling pattern FIL may include an insulating material.

A data storage pattern DSP may be provided on the landing pad LP. A plurality of data storage patterns DSP may be provided, and the data storage patterns DSP may be spaced apart from each other in the first and second directions D1 and D2. Each of the data storage patterns DSP may vertically overlap at least a portion of the corresponding landing pad LP. As an example, each of the data storage patterns DSP may vertically overlap all of the corresponding landing pads LP. As another example, each of the data storage patterns DSP may be shifted further in the first direction D1 or in a direction opposite to the first direction D1 than the landing pad LP, and may perpendicularly overlap a portion of the landing pad LP. The data storage pattern DSP may be electrically connected to one of the first and second edge portions EA1 and EA2 of the corresponding activation pattern ACT through the corresponding landing pad LP and the corresponding storage node contact BC.

The data storage pattern DSP may be, for example, a capacitor including a lower electrode, a dielectric layer, and an upper electrode. In this case, the semiconductor device according to the inventive concepts may be a dynamic random access memory (DRAM). As another example, the data storage pattern DSP may include a magnetic tunnel junction pattern. In this case, the semiconductor device according to the inventive concepts may be a magnetic random access memory (MRAM). As another example, the data storage pattern DSP may include a phase change material or a variable resistance material. In this case, the semiconductor device according to the inventive concepts may be a phase-change random access memory (PRAM) or a resistive random access memory (ReRAM). However, this is only an example and the inventive concepts are not limited thereto, and the data storage pattern DSP may include various structures and/or materials capable of storing data.

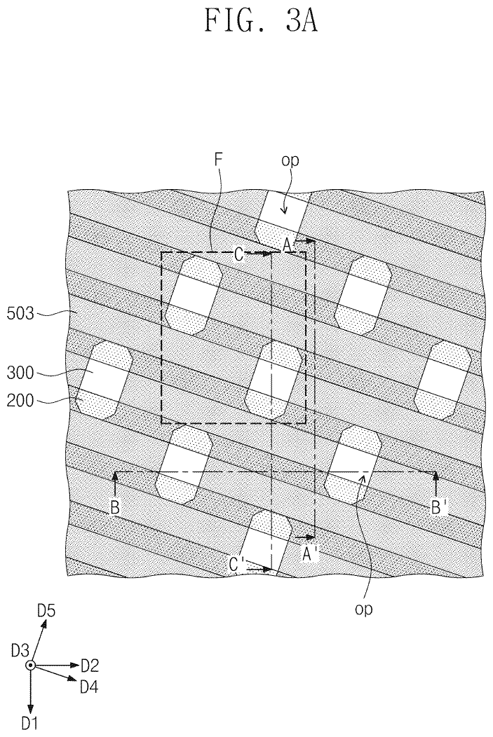

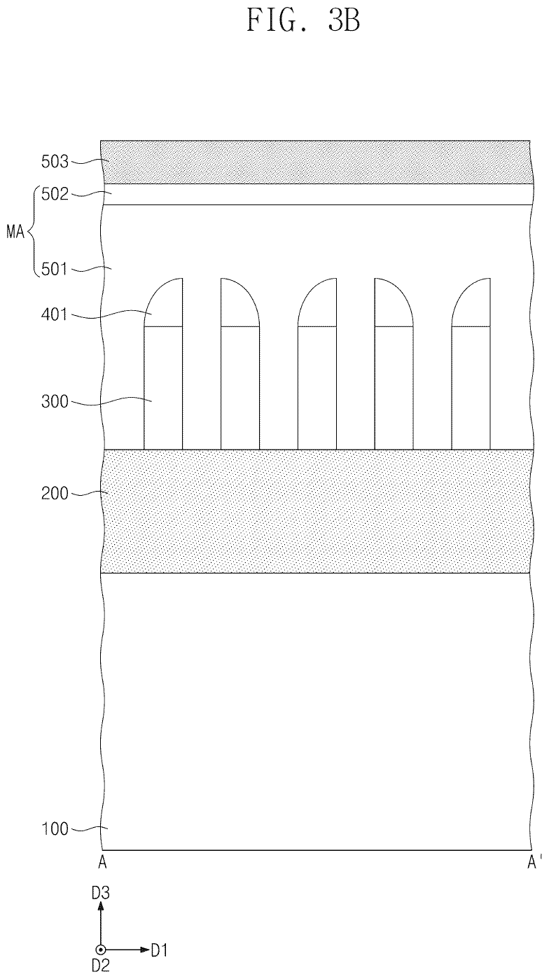

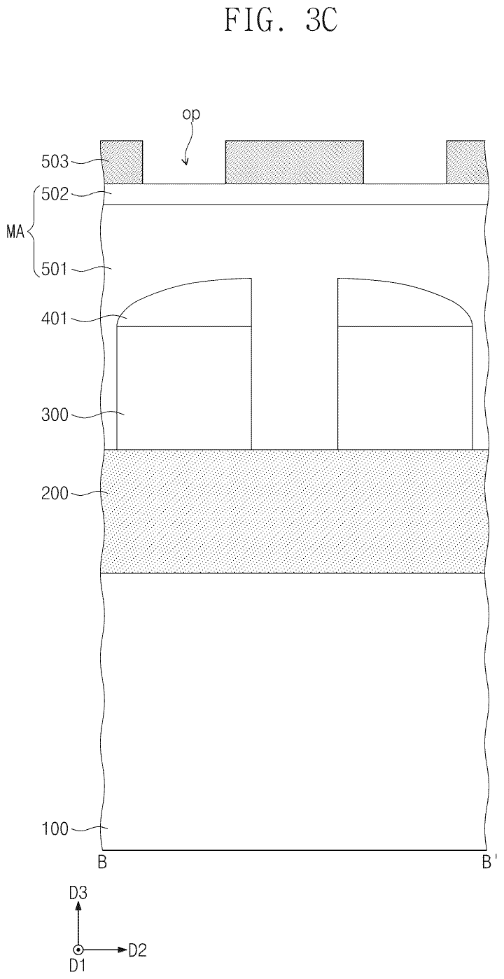

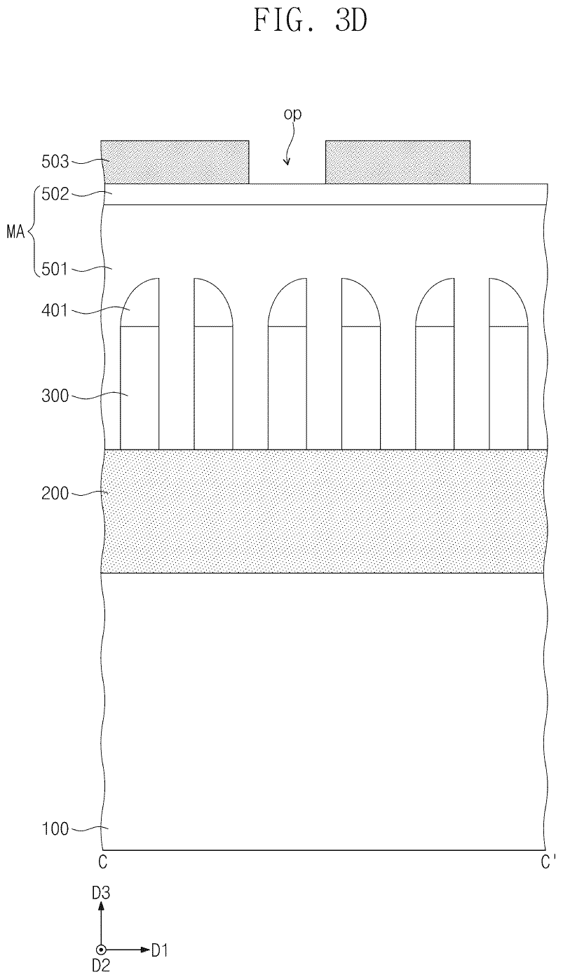

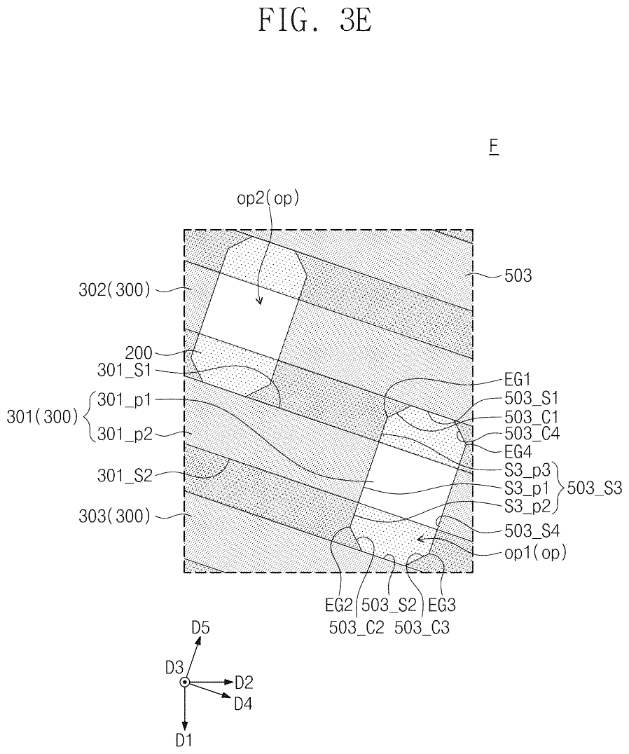

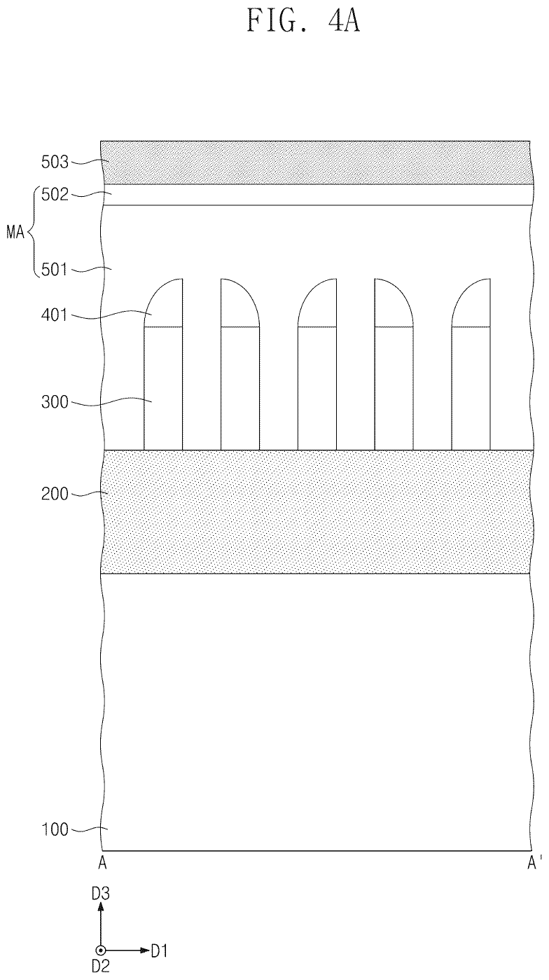

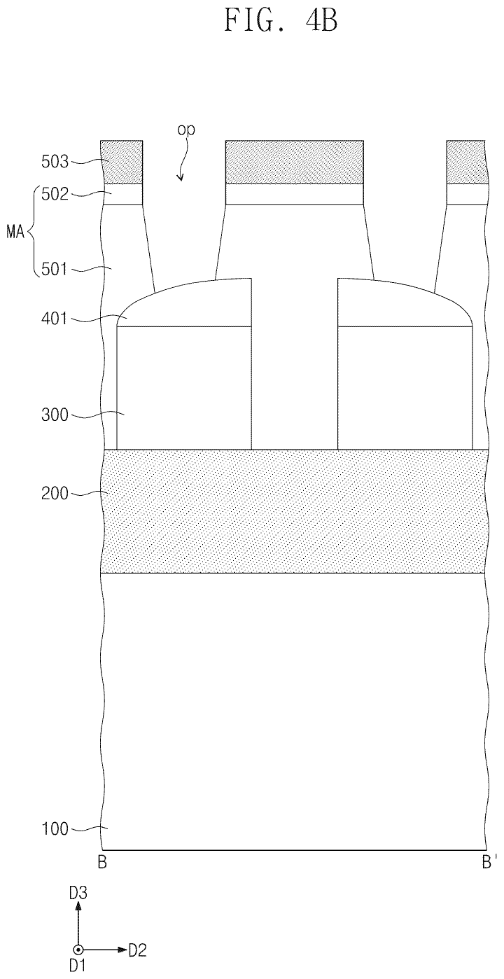

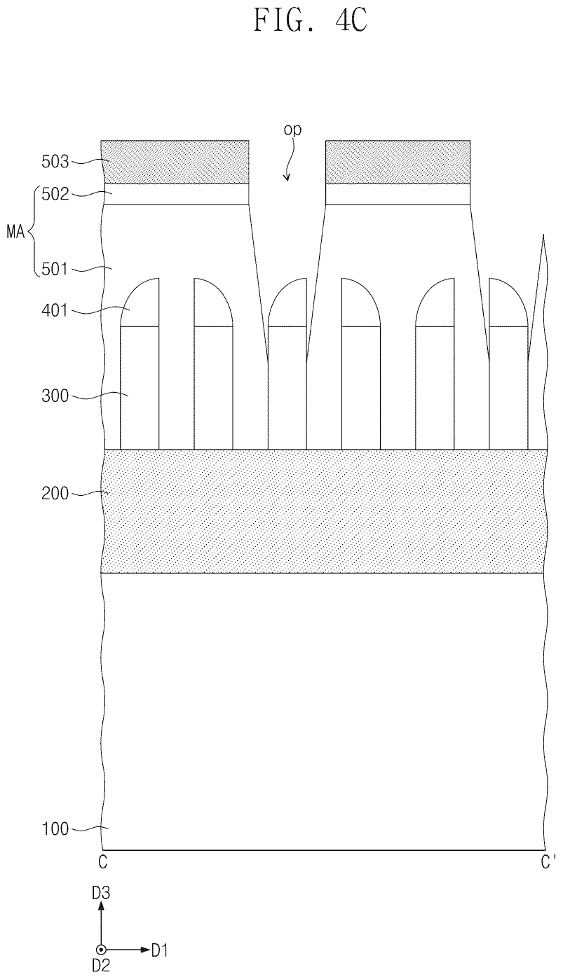

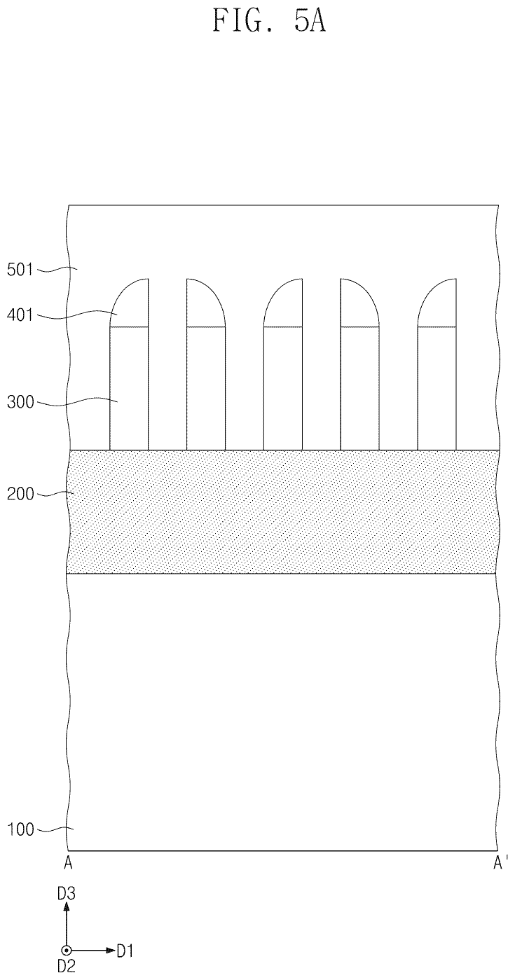

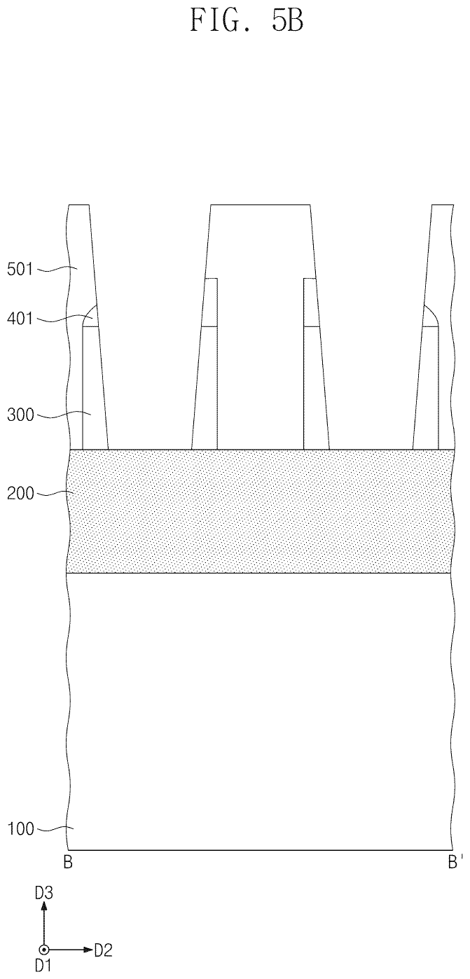

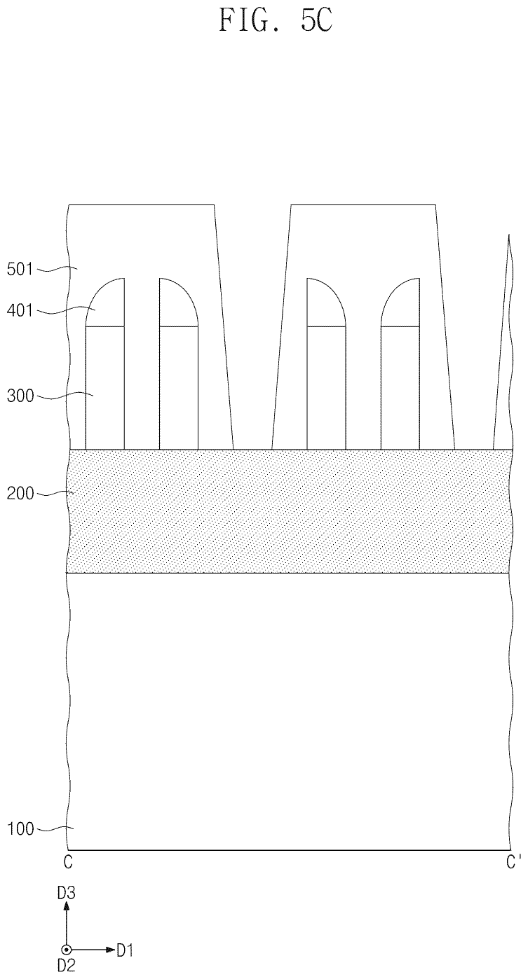

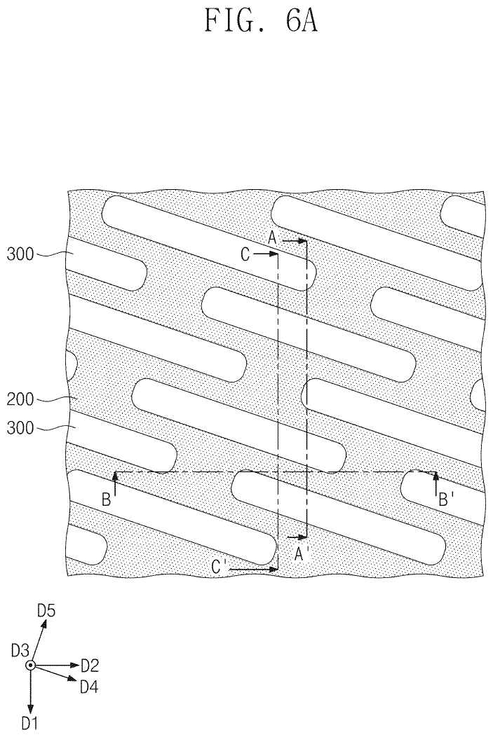

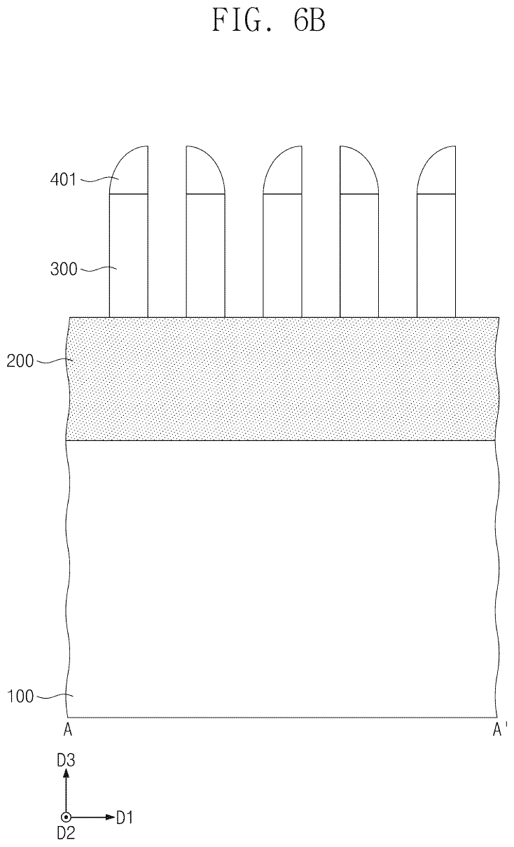

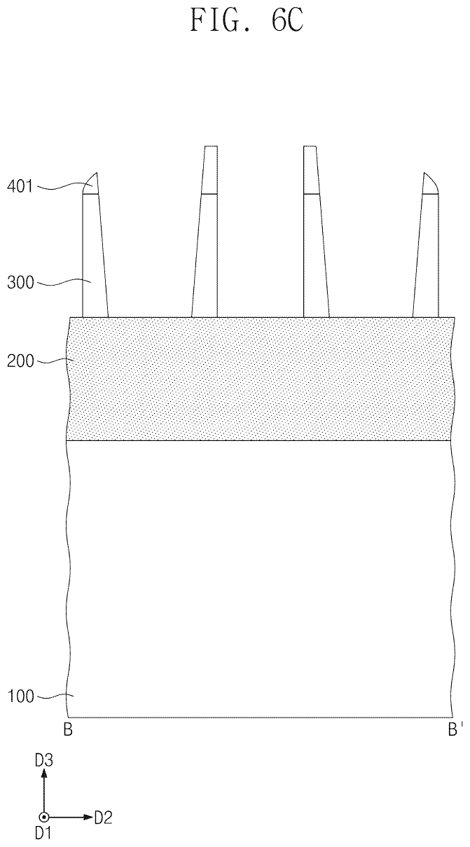

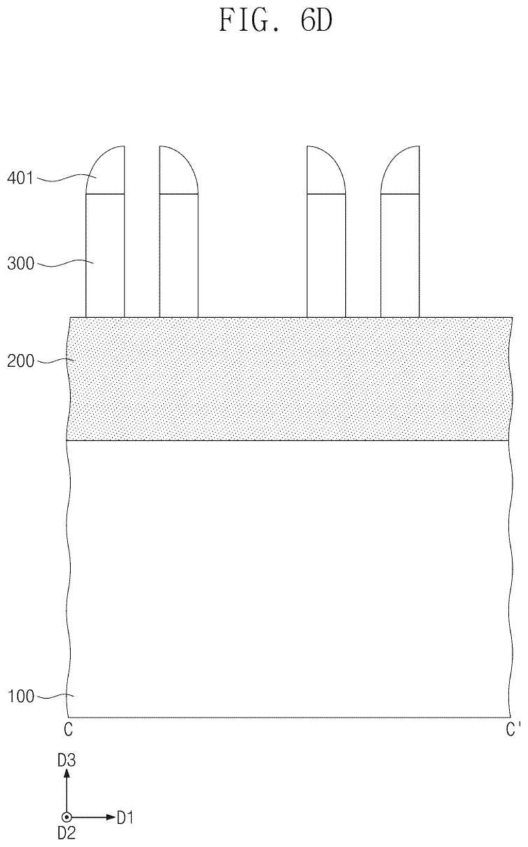

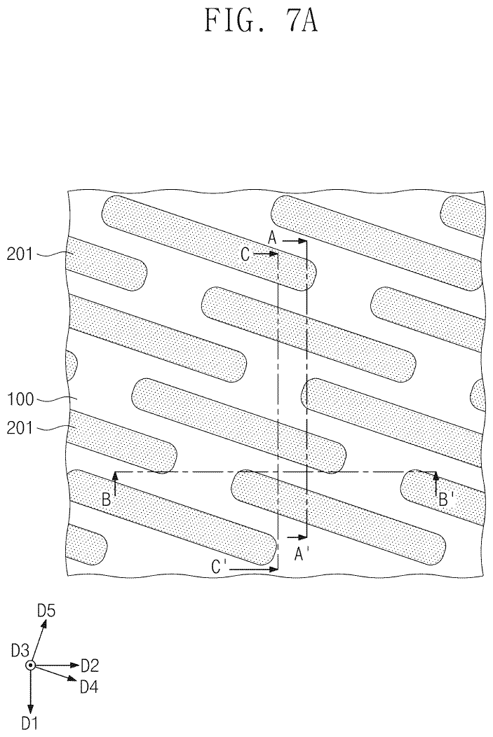

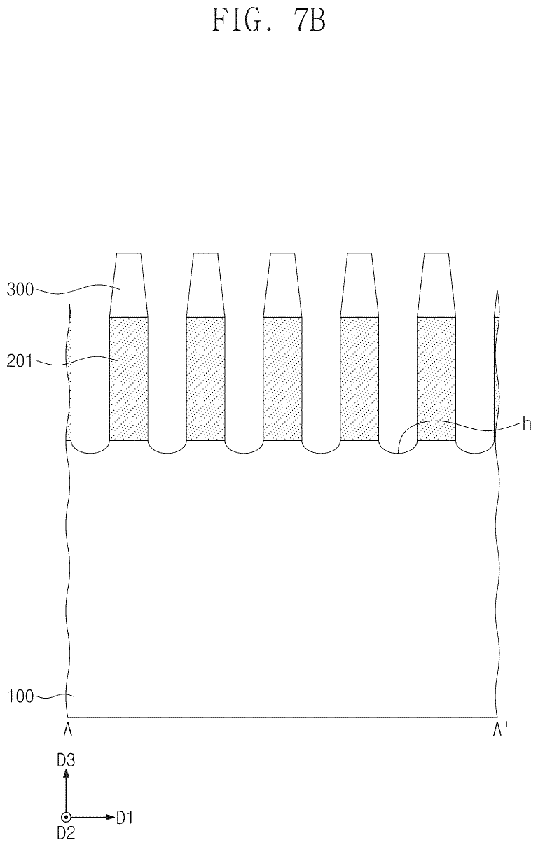

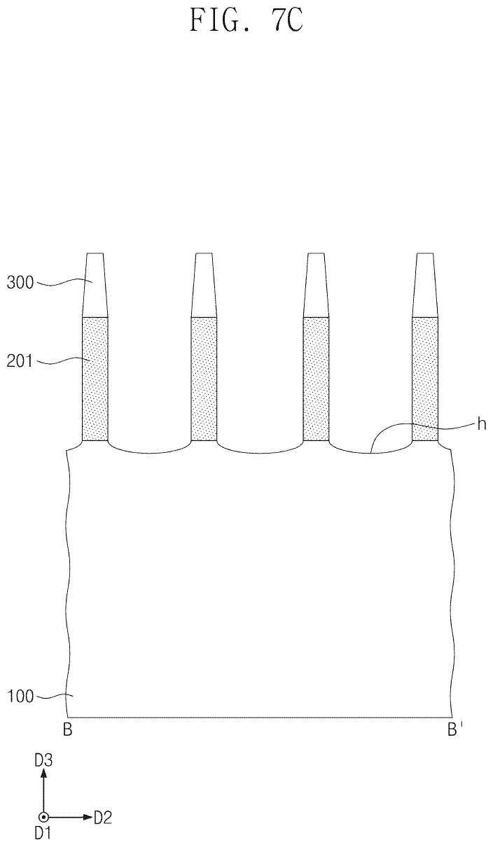

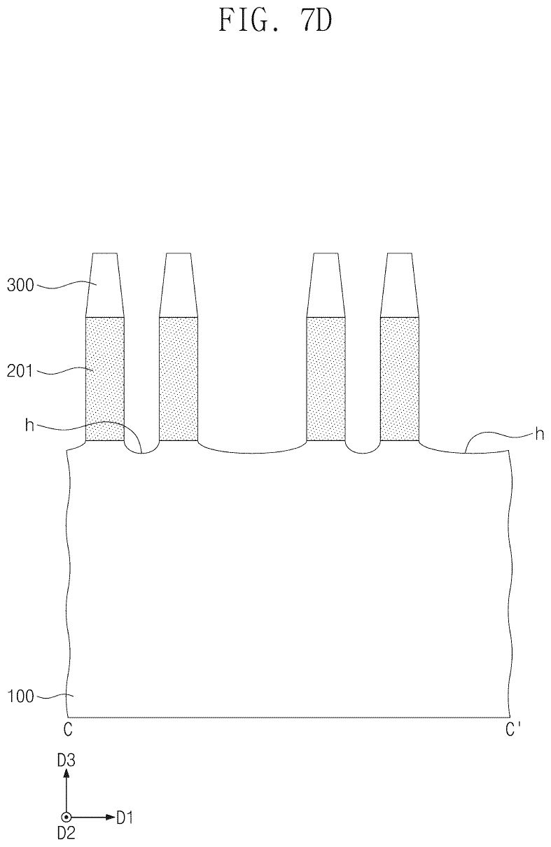

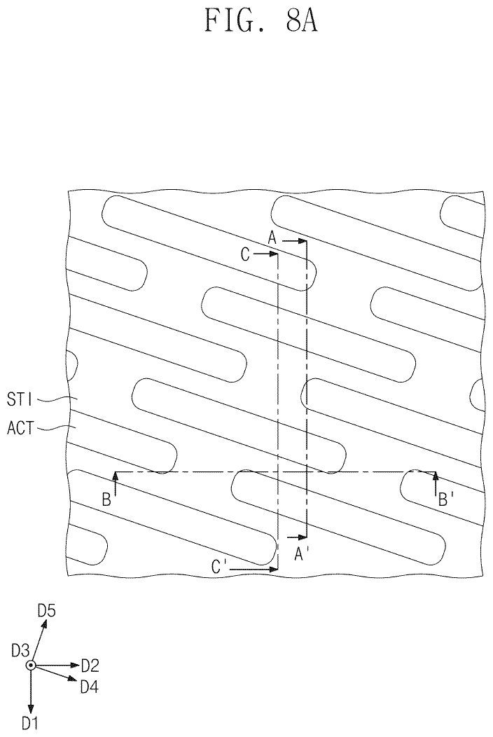

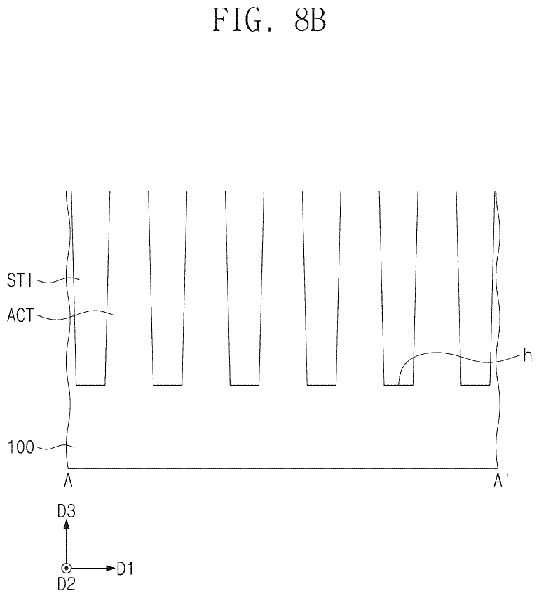

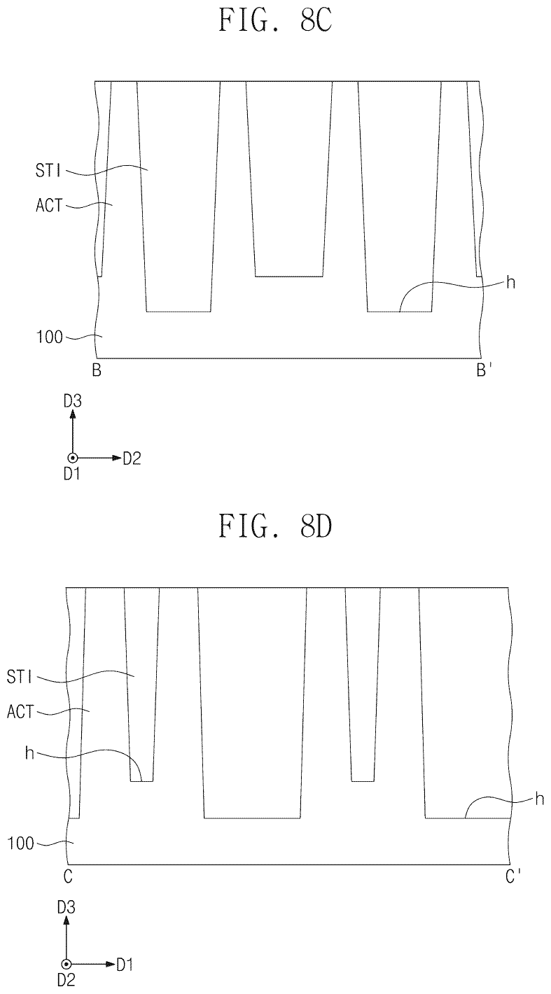

FIG. 2A, 3A, 6A, 7A, and 8A are enlarged views of region ‘E’ in FIG. 1A for explaining a method of manufacturing a semiconductor device according to some example embodiments. FIG. 3E is an enlarged view of region ‘F’ in FIG. 3A. FIGS. 2B, 2C, 2D, 3B, 3C, 3D, 4A, 4B, 4C, 5A, 5B, 5C, 6B, 6C, 6D, 7B, 7C, 7D, 8B, 8C, and 8D are cross-sectional views for explaining a method of manufacturing a semiconductor device according to some example embodiments. FIG. 2A, 3A, 6A, 7A, and 8A correspond FIG. 1B. FIGS. 2B, 3B, 4A, 5A, 6B, 7B and 8B may correspond to FIG. 1C. FIGS. 2C, 3C, 4B, 5B, 6C, 7C and 8C may correspond to FIG. 1D. FIGS. 2D, 3D, 4C, 5C, 6D, 7D and 8D may correspond to FIG. 1E.

Referring to FIGS. 2A to 2D, a substrate 100 may be provided. A lower insulating layer 200 may be formed on the substrate 100. The lower insulating layer 200 may conformally cover an upper surface of the substrate 100. The lower insulating layer 200 may include an insulating material. As an example, the lower insulating layer 200 may include oxide.

Line patterns 300 and insulating spacers 401 may be formed on the lower insulating layer 200. Forming the line patterns 300 and insulating spacers 401 may include forming insulating layers not shown on the lower insulating layer 200, and patterning the insulating layers to form the line patterns 300 and the insulating spacers 401.

Each of the line patterns 300 may protrude in a third direction D3. Each of the line patterns 300 may extend in a fourth direction D4. The line patterns 300 may be spaced apart from each other in a fifth direction D5. The line patterns 300 may be arranged at regular intervals in the fifth direction D5. A portion of an upper surface of the lower insulating layer 200 may be exposed through between the line patterns 300. The line pattern 300 may include a material having an etch selectivity with respect to the lower insulating layer 200. As an example, the line pattern 300 may include a polymer material.

Each of the insulating spacers 401 may be formed on the line pattern 300. The insulating spacer 401 may include an insulating material. As an example, the insulating spacer 401 may include oxide.

Referring to FIGS. 3A to 3D, a mask structure MA may be formed on the lower insulating layer 200, the line patterns 300, and the insulating spacers 401. The mask structure MA may include a first mask layer 501 and a second mask layer 502 on the first mask layer 501.

The first mask layer 501 may cover the lower insulating layer 200, the line patterns 300, and the insulating spacers 401. The first mask layer 501 may fill a space between the line patterns 300. The first mask layer 501 may cover the upper surface of the lower insulating layer 200 exposed between the line patterns 300. The first mask layer 501 may include a material that has an etch selectivity with respect to the line patterns 300 and the insulating spacers 401. As an example, the first mask layer 501 may include a carbon-based polymer material.

The second mask layer 502 may cover an upper surface of the first mask layer 501. The second mask layer 502 may include a material that has an etch selectivity with respect to the first mask layer 501. As an example, the second mask layer 502 may include nitride.

A photoresist pattern 503 may be formed on the second mask layer 502. Forming the photoresist pattern 503 may include forming a preliminary photoresist pattern, and performing an exposure process and a development process on the preliminary photoresist pattern to form the photoresist pattern 503.

The photoresist pattern 503 may include openings op. The openings op of the photoresist pattern 503 may be arranged at regular intervals in the fourth direction D4 and the fifth direction D5. The openings op of the photoresist pattern 503 may be offset from each other. A portion of an upper surface of the second mask layer 502 may be exposed through the opening op of the photoresist pattern 503. The opening op of the photoresist pattern 503 may overlap the line patterns 300. The photoresist pattern 503 may include a photoresist material.

Referring to FIG. 3E, the line patterns 300 may include a first line pattern 301, a second line pattern 302, and a third line pattern 303. The second line pattern 302 and the third line pattern 303 may be adjacent to the first line pattern 301. The second line pattern 302 and the third line pattern 303 may be spaced apart from each other in the fifth direction D5 with the first line pattern 301 interposed therebetween.

The openings op may include a first opening op1 and a second opening op2. The second opening op2 may be similar to the first opening op1. The first line pattern 301 may overlap the first opening op1. The second line pattern 302 and the third line pattern 303 may not overlap the first opening op1. The second line pattern 302 may overlap the second opening op2. The first line pattern 301 and the third line pattern 303 may not overlap the second opening op2.

The first opening op1 may include a first inner wall 503_S1, a second inner wall 503_S2, a third inner wall 503_S3, a fourth inner wall 503_S4, a first connection surface 503_C1, and a second connection surface 503_C2, a third connection surface 503_C3, a fourth connection surface 503_C4, a first edge EG1, a second edge EG2, a third edge EG3, and a fourth edge EG4.

The first inner wall 503_S1 and the second inner wall 503_S2 of the first opening op1 may face each other. The first inner wall 503_S1 and the second inner wall 503_S2 of the first opening op1 may be parallel to the fourth direction D4. The first inner wall 503_S1 and the second inner wall 503_S2 of the first opening op1 may not overlap the first line pattern 301. The third inner wall 503_S3 and the fourth inner wall 503_S4 of the first opening op1 may face each other. The third inner wall 503_S3 and the fourth inner wall 503_S4 of the first opening op1 may be parallel to the fourth direction D4. The third inner wall 503_S3 and the fourth inner wall 503_S4 of the first opening op1 may be disposed between the first inner wall 503_S1 and the second inner wall 503_S2 of the first opening op1. The third inner wall 503_S3 and the fourth inner wall 503_S4 of the first opening op1 may overlap the first line pattern 301.

The first connection surface 503_C1 of the first opening op1 may connect the first inner wall 503_S1 and the third inner wall 503_S3 of the first opening op1. The second connection surface 503_C2 of the first opening op1 may connect the second inner wall 503_S2 and the third inner wall 503_S3 of the first opening op1. The third connection surface 503_C3 of the first opening op1 may connect the second inner wall 503_S2 and the fourth inner wall 503_S4 of the first opening op1. The fourth connection surface 503_C4 of the first opening op1 may connect the first inner wall 503_S1 and the fourth inner wall 503_S4 of the first opening op1. The first to fourth connection surfaces 503_C1, 503_C2, 503_C3, and 503_C4 of the first opening op1 may not overlap the line patterns 300. The first connection surface 503_C1 and the fourth connection surface 503_C4 of the first opening op1 may be disposed between the first line pattern 301 and the second line pattern 302. The second connection surface 503_C2 and the third connection surface 503_C3 of the first opening op1 may be disposed between the first line pattern 301 and the third line pattern 303.

The first connection surface 503_C1 and the third inner wall 503_S3 of the first opening op1 may meet at the first edge EG1 of the first opening op1. The second connection surface 503_C2 and the third inner wall 503_S3 of the first opening op1 may meet at the second edge EG2 of the first opening op1. The third connection surface 503_C3 and the fourth inner wall 503_S4 of the first opening op1 may meet at the third edge EG3 of the first opening op1. The fourth connection surface 503_C4 and the fourth inner wall 503_S4 of the first opening op1 may meet at the fourth edge EG4 of the first opening op1. The first edge EG1 and the fourth edge EG4 of the first opening op1 may be disposed between the first line pattern 301 and the second line pattern 302. The second edge EG2 and the third edge EG3 of the first opening op1 may be disposed between the first line pattern 301 and the third line pattern 303. The first to fourth edges EG1, EG2, EG3, and EG4 of the first opening op1 may not overlap the line patterns 300.

The third inner wall 503_S3 of the first opening op1 may include a first portion S3_p1, a second portion S3_p2, and a third portion S3_p3. The first portion S3_p1 of the third inner wall 503_S3 may overlap the first line pattern 301. The second portion S3_p2 and the third portion S3_p3 of the third inner wall 503_S3 may not overlap the first line pattern 301. The second portion S3_p2 of the third inner wall 503_S3 may be disposed between the first line pattern 301 and the second line pattern 302. The third portion S3_p3 of the third inner wall 503_S3 may be disposed between the first line pattern 301 and the third line pattern 303. The second portion S3_p2 and the third portion S3_p3 of the third inner wall 503_S3 may be spaced apart from each other with the first portion S3_p1 of the third inner wall 503_S3 interposed therebetween.

The first line pattern 301 may include a first sidewall 301_S1 and a second sidewall 301_S2 opposite to the first sidewall 301_S1. The first and second sidewalls 301_S1, 301_S2 of the first line pattern 301 may be parallel to the fourth direction D4. The first sidewall 301_S1 of the first line pattern 301 may face the second line pattern 302. The second sidewall 301_S2 of the first line pattern 301 may face the third line pattern 303. The first sidewall 301_S1 and the second sidewall 301_S2 of the first line pattern 301 may be parallel to the first inner wall 503_S1 and the second inner wall 503_S2 of the first opening op1. The first and second sidewalls of the first line pattern 301 may be perpendicular to the third inner wall 503_S3 and the fourth inner wall 503_S4 of the first opening op1.

The first line pattern 301 may include a first line portion 301_p1 that overlaps the first opening op1 and a second line portion 301_p2 that does not overlap the first opening op1. The first line portion 301_p1 of the first line pattern 301 may have a rectangular shape when viewed in a plan.

A distance in the fifth direction D5 between the first inner wall 503_S1 and the second inner wall 503_S2 of the first opening op1 may be substantially equal to or smaller than a distance between the second line pattern 302 and the third line pattern 303 in the fifth direction D5. A length of the second portion S3_p2 of the third inner wall 503_S3 may be the same as a length of the third portion S3_p3 of the third inner wall 503_S3. A length of the first portion S3_p1 of the third inner wall 503_S3 may be substantially equal to a width of the first line pattern 301 in the fifth direction D5. A width of the first line portion 301_p1 of the first line pattern 301 in the fourth direction D4 may be the same as a shortest distance between the second inner wall 503_S2 and the fourth inner wall 503_S4 of the first opening op1. The shortest distance between the second line pattern 302 and the third line pattern 303 may be substantially equal to the maximum width of the first opening op1 in the fifth direction D5. A distance between the first sidewall 301_S1 of the first line pattern 301 and the first inner wall 503_S1 of the first opening op1 in the fifth direction D5 may be substantially constant. A distance between the second sidewall 301_S2 of the first line pattern 301 and the second inner wall 503_S2 of the first opening op1 in the fifth direction D5 may be substantially constant.

Referring to FIGS. 4A to 4C, the second mask layer 502 and the first mask layer 501 may be etched through the openings op using the photoresist pattern 503 as an etch mask. The openings op may further include empty spaces formed by etching the second mask layer 502 and the first mask layer 501. The line patterns 300 and the insulating spacers 401 may be exposed through the openings op. In some example embodiments, the second mask layer 502 and the first mask layer 501 may be etched through a dry etch process.

Referring to FIGS. 5A to 5C, using the second mask layer 502 and the first mask layer 501 as an etch mask, the first mask layer 501, the insulating spacers 401, and the line pattern 300 may be etched through the openings op. One line pattern 300 extending in the fourth direction D4 may be etched and separated into a plurality of line patterns 300 arranged in the fourth direction D4. The openings op may further include empty spaces formed by etching the first mask layer 501, the insulating spacers 401, and the line patterns 300. A portion of the upper surface of the lower insulating layer 200 may be exposed through the opening op. After the first mask layer 501, the insulating spacers 401, and the line patterns 300 are etched, the second mask layer 502 may be removed. In some example embodiments, the first mask layer 501, the insulating spacers 401, and the line patterns 300 may be etched through a dry etch process. In some example embodiments, the second mask layer 502 may be removed through an ashing process.

Referring to FIGS. 6A to 6C, the first mask layer 501 may be removed. The first mask layer 501 may be removed, such that sidewalls of the line patterns 300 may be completely exposed. A portion of the upper surface of the lower insulating layer 200 may be exposed between the line patterns 300. In some example embodiments, the first mask layer 501 may be removed through an ashing process.

Referring to FIGS. 7A to 7D, the lower insulating layer 200 and the line patterns 300 may be etched using the line patterns 300 as an etch mask. The lower insulating layer 200 may be etched and separated into a plurality of lower patterns 201. An upper portion of the line pattern 300 may be etched, so that only a lower portion of the line pattern 300 may remain.

When the lower insulating layer 200 is etched, a portion of an upper surface of the substrate 100 exposed between the line patterns 300 may be removed. The portion of the upper surface of the substrate 100 may be removed to form an isolation trench h. The isolation trench h may be defined by a surface of the substrate 100 formed by removing the portion of the upper surface of the substrate 100. The isolation trenches h may be disposed between the line patterns 300.

Referring to FIGS. 8A to 8D, the substrate 100 may be etched using the lower patterns 201 as an etch mask. The substrate 100 may be etched to form active patterns ACT. The active patterns ACT may be portions that protrude in the third direction D3 remaining after the substrate 100 is etched. The substrate 100 may be etched to expand the isolation trench h. The isolation trench h may further include an empty space formed by etching the substrate. The isolation trench h may be disposed between adjacent active patterns ACT.

A device isolation layer STI may be formed. The device isolation layer STI may be formed in the isolation trench h. The device isolation layer STI may fill the empty space between adjacent active patterns ACT.

Referring again to FIGS. 1A to 1E, word lines WL may be formed on the device isolation layer STI. A buffer pattern BP, an insulation pattern PP, storage node contacts BC, bit line contacts DC, bit lines BL, bit line capping patterns BCP, bit line spacers BSP, fence patterns FN, landing pads LP, filling patterns FIL, and data storage patterns DSP may be formed.

In a method of manufacturing a semiconductor device according to some example embodiments, the photoresist pattern 503 including the opening op orthogonal to a line and space may be used, thereby more uniformly forming the active patterns ACT. Accordingly, the storage node contacts BC and the bit line contacts DC may be accurately connected to the active patterns ACT, thereby improving electrical characteristics and reliability of the semiconductor device.

The method of manufacturing the semiconductor device according to embodiments of the inventive concepts may form the active patterns more uniformly by using the photoresist pattern including openings orthogonal to lines and spaces. Accordingly, the storage node contacts and the bit line contacts may be accurately connected to the active patterns, thereby improving the electrical characteristics and reliability of the semiconductor device.

While some example embodiments are described above, a person skilled in the art may understand that many modifications and variations are made without departing from the spirit and scope of the inventive concepts defined in the following claims. Accordingly, the example embodiments of the inventive concepts should be considered in all respects as illustrative and not restrictive, with the spirit and scope of the inventive concepts being indicated by the appended claims.

What is claimed is:

1. A method of manufacturing a semiconductor device, the method comprising:
providing a substrate;
forming a lower insulating layer on the substrate;
forming line patterns extending in a first direction on the lower insulating layer, the line patterns being spaced apart from each other in a second direction, the second direction being perpendicular to the first direction;
forming a mask structure on the line patterns;
forming a photoresist pattern including a first opening on the mask structure;
etching the mask structure using the photoresist pattern as a first etch mask;
etching the line patterns using the etched mask structure as a second etch mask;
etching the lower insulating layer using the etched line patterns as a third etch mask to form lower patterns; and
etching the substrate using the lower patterns as a fourth etch mask,
wherein the line patterns include
a first line pattern overlapping the first opening, and
a second line pattern and a third line pattern adjacent to the first line pattern,
the first opening includes
a first inner wall,
a second inner wall facing the first inner wall, and
a third inner wall between the first and second inner walls,
the third inner wall overlaps the first line pattern, and
a distance in the second direction between the first and second inner walls of the first opening is equal to or smaller than a distance in the second direction between the second and third line patterns.

2. The method of claim 1, wherein the first line pattern includes a line portion overlapping the first opening, and
the line portion has a rectangular shape in a plan view.

3. The method of claim 2, wherein the first opening further includes a fourth inner wall facing the third inner wall, and
a width of the line portion of the first line pattern in the first direction is equal to a shortest distance between the second and fourth inner walls of the first opening.

4. The method of claim 1, wherein
the third inner wall of the first opening includes:
a first portion overlapping the first line pattern;
a second portion between the first and second line patterns; and
a third portion between the first and third line patterns, and
wherein the second and third portions of the third inner wall are spaced apart from each other with the first portion of the third inner wall therebetween.

5. The method of claim 4, wherein a length of the second portion of the third inner wall is equal to a length of the third portion of the third inner wall.

6. The method of claim 4, wherein a width of the first line pattern in the second direction is equal to a length of the first portion of the third inner wall.

7. The method of claim 1, wherein a shortest distance between the second and third line patterns is equal to a maximum width of the first opening in the second direction.

8. The method of claim 1, wherein
the first line pattern includes a sidewall facing the second line pattern, and
the sidewall of the first line pattern is parallel to the first direction.

9. The method of claim 1, wherein
the first opening overlaps the first line pattern, and
the first opening does not overlap the second and third line patterns.

10. The method of claim 9, wherein
the photoresist pattern further includes a second opening overlapping the second line pattern, and
the second opening does not overlap the first line pattern.

11. A method of manufacturing a semiconductor device, the method comprising:
providing a substrate;
forming a lower insulating layer on the substrate;
forming line patterns extending in a first direction on the lower insulating layer, the line patterns being spaced apart from each other in a second direction, the second direction being perpendicular to the first direction;
forming a mask structure on the line patterns;
forming a photoresist pattern including an opening on the mask structure;
etching the mask structure using the photoresist pattern as a first etch mask;
etching the line patterns using the etched mask structure as a second etch mask;
etching the lower insulating layer using the etched line patterns as a third etch mask to form lower patterns; and
etching the substrate using the lower patterns as a fourth etch mask,
wherein the opening includes
a first inner wall and a second inner wall parallel to the first direction, and
a third inner wall and a fourth inner wall parallel to the second direction.

12. The method of claim 11, wherein the opening includes:
a first connection surface connecting the first and third inner walls;
a second connection surface connecting the second and third inner walls;
a third connection surface connecting the second and fourth inner walls; and
a fourth connection surface connecting the first and fourth inner walls, and
wherein the first to fourth connection surfaces do not overlap the line patterns.

13. The method of claim 12, wherein the line patterns include:
a first line pattern overlapping the opening; and
a second line pattern and a third line pattern adjacent to the first line pattern,
wherein the first and fourth connection surfaces are between the first and second line patterns, and
wherein the second and third connection surfaces are between the first and third line patterns.

14. The method of claim 11, wherein the line patterns include:
a first line pattern overlapping the opening; and
a second line pattern and a third line pattern adjacent to the first line pattern,
wherein the first line pattern includes a sidewall facing the second line pattern, and
the sidewall of the first line pattern is orthogonal to the third inner wall and the fourth inner wall of the opening.

15. The method of claim 14, wherein the sidewall of the first line pattern is parallel to the first inner wall and the third inner wall of the opening.

16. The method of claim 14, wherein a distance in the second direction between the sidewall of the first line pattern and the first inner wall of the opening is constant.

17. A method of manufacturing a semiconductor device, the method comprising:
providing a substrate;
forming a lower insulating layer on the substrate;
forming line patterns extending in a first direction on the lower insulating layer, the line patterns being spaced apart from each other in a second direction, the second direction being perpendicular to the first direction;
forming a mask structure on the line patterns;
forming a photoresist pattern including an opening on the mask structure;
etching the mask structure using the photoresist pattern as a first etch mask;
etching the line patterns using the etched mask structure as a second etch mask;
etching the lower insulating layer using the etched line patterns as a third etch mask to form lower patterns; and
etching the substrate using the lower patterns as a fourth etch mask,
wherein the line patterns include
a first line pattern overlapping the opening, and
a second line pattern and a third line pattern adjacent to the first line pattern,
the opening includes
a first inner wall,
a second inner wall facing the first inner wall,
a third inner wall between the first and second inner walls,
a first connection surface connecting the first and third inner walls, and
a second connection surface connecting the second and third inner walls,
the first connection surface is between the first and second line patterns, and
the second connection surface is between the first and third line patterns.

18. The method of claim 17, wherein the first and second connection surfaces of the opening do not overlap the line patterns.

19. The method of claim 17, wherein the opening includes:
a first edge where the first connection surface and the third inner wall meet; and
a second edge where the second connection surface and the third inner wall meet,
wherein the first edge is between the first and second line patterns, and
the second edge is between the first and third line patterns.

20. The method of claim 19, wherein the first edge and the second edge do not overlap the line patterns.
